(19) United States
(12) Patent Application Publication
(10) Pub. No.: US 2024/0174558 A1
(43) Pub. Date: May 30, 2024

(54) DISPLAY DEVICE AND MANUFACTURING METHOD OF THE SAME

(71) Applicant: Samsung Display Co., LTD., Yongin-si (KR)

(72) Inventors: JEONGWEON SEO, Yongin-si (KR); SUK WON JUNG, Yongin-si (KR); HYUK-HWAN KIM, Yongin-si (KR)

(21) Appl. No.: 18/227,549

(22) Filed: Jul. 28, 2023

(30) Foreign Application Priority Data
Nov. 24, 2022 (KR) 10-2022-0159199

(51) Int. Cl. C03C 17/42; H05K 5/03

(52) U.S. Cl. CPC C03C 17/42; H05K 5/03; C03C 2217/213; C03C 2217/281

(57) ABSTRACT

A method for manufacturing a display device includes preparing a display panel, depositing a plurality of inorganic films having different thermal expansion coefficients, respectively, on the display panel, loading the display panel on a stage, heating the stage, coating the display panel with a resin for a cover panel, and cooling the stage.

This application claims priority to Korean Patent Application No. 10-2022-0159199, filed on Nov. 24, 2022, and all the benefits accruing therefrom under 35 U.S.C. § 119, the content of which in its entirety is herein incorporated by reference.

### BACKGROUND

### 1. Field

The disclosure herein relates to a display device and a manufacturing method thereof, and more particularly, to a display device to which a single-layered cover panel is applied and a manufacturing method for forming the cover panel by screen printing.

### 2. Description of the Related Art

A display device is used in various multimedia devices such as televisions, mobile phones, tablet computers, and game machines to provide image information to a user. The display device may include a display module which provides image information and a cover panel which protects the display module from the outside.

The cover panel protects the display module from the outside by preventing the display module from being deformed by an impact, shielding electromagnetic waves, and radiating heat. In order to provide various functions for protecting the display module, a structure in which a plurality of functional layers is stacked is applied to the cover panel.

Research is being conducted on a display device, to which a single-layered cover panel integrally having various functions for protecting the display module is applied, and a method for manufacturing the same.

### SUMMARY

The disclosure provides a display device including an integral cover panel with improved flatness.

The disclosure also provides a method for manufacturing the display device, by which an integral cover panel is formed by applying a screen-printing process which improves coating quality.

An embodiment of the inventive concept provides a method for manufacturing a display device including preparing a display panel: depositing a plurality of inorganic films having different thermal expansion coefficients, respectively, on the display panel: loading the display panel on a stage; heating the stage: coating the display panel with a resin for a cover panel: and cooling the stage.

In an embodiment, the heating may include bending an edge portion of the display panel in a direction opposite to the stage by heating.

In an embodiment, the heating may include pushing an edge portion of the display panel in a direction opposite to the stage with a pusher.

In an embodiment, the cooling may include bending an edge portion of the display panel in a direction of the stage by cooling.

In an embodiment, the cooling may include flattening an edge portion of a coated resin.

In an embodiment, the depositing the plurality of inorganic films may include depositing a first inorganic film on the display panel and a second inorganic film on the first inorganic film, a thermal expansion coefficient of the first inorganic film may be smaller than a thermal expansion coefficient of the second inorganic film, and the loading may include loading the second inorganic film adjacent to the stage.

In an embodiment, the heating the stage may include bending edge portions of the plurality of inorganic films in a direction of the display panel as the second inorganic film expands more than the first inorganic film.

In an embodiment, the depositing the plurality of inorganic films may include depositing a first inorganic film on the display panel and a second inorganic film on the first inorganic film, a thermal expansion coefficient of the first inorganic film may be greater than a thermal expansion coefficient of the second inorganic film, and the loading may include loading the display panel adjacent to the stage.

In an embodiment, the heating the stage may include bending edge portions of the plurality of inorganic films in a direction opposite to the display panel as the first inorganic film expands more than the second inorganic film.

In an embodiment, the coating the resin may further include disposing a mask, in which an opening is defined, on the display panel: coating the resin; and separating the mask.

In an embodiment, the method may further include curing the resin.

In an embodiment, the depositing the plurality of inorganic films may include sequentially depositing a first inorganic film, a second inorganic film, and a third inorganic film on the display panel, a thermal expansion coefficient of the first inorganic film may be smaller than a thermal expansion coefficient of the third inorganic film, a thermal expansion coefficient of the second inorganic film may have a value between the thermal expansion coefficient of the first inorganic film and the thermal expansion coefficient of the third inorganic film, and the loading may include loading the third organic film adjacent to the stage.

In an embodiment, the depositing the plurality of inorganic films may include sequentially depositing a first inorganic film, a second inorganic film, and a third inorganic film on the display panel, a thermal expansion coefficient of the first inorganic film may be greater than a thermal expansion coefficient of the third inorganic film, a thermal expansion coefficient of the second inorganic film may have a value between the thermal expansion coefficient of the first inorganic film and the thermal expansion coefficient of the third inorganic film, and the loading may include loading the display panel adjacent to the stage.

In an embodiment of the inventive concept, a method for manufacturing a display device includes preparing a display panel: depositing a plurality of inorganic films on the display panel: loading the display panel on a stage: bending an edge portion of the display panel in a direction opposite to the stage: coating the display panel with a resin for a cover panel: and flattening the bent edge portion of the display panel.

In an embodiment, the plurality of inorganic films may respectively have thermal expansion coefficients different from each other.

In an embodiment, the bending the edge portion of the display panel in a direction opposite to the stage may include heating the stage.

In an embodiment, the flattening a bent edge portion of the display panel may include cooling the stage.

In an embodiment of the inventive concept, a display device includes: a cover panel: a display panel disposed on the cover panel: and a plurality of inorganic films having different thermal expansion coefficients, respectively, and disposed on the cover panel.

In an embodiment, the plurality of inorganic films may be spaced apart from the cover panel with the display panel interposed therebetween, the plurality of inorganic films may include a first inorganic film disposed in contact with the display panel and a second inorganic film disposed on the first inorganic film, and a thermal expansion coefficient of the first inorganic film may be smaller than that of the second inorganic film.

In an embodiment, the plurality of inorganic films may be disposed between the display panel and the cover panel, the plurality of inorganic films may include a first inorganic film disposed in contact with the display panel and a second inorganic film disposed on the first inorganic film, and a thermal expansion coefficient of the first inorganic film may be greater than that of the second inorganic film.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a combined perspective view of an embodiment of a display device according to the inventive concept:

FIG. 2 is an exploded perspective view of an embodiment of the display device according to the inventive concept:

FIGS. 3A and 3B are cross-sectional views of an embodiment of the display device according to the inventive concept, respectively:

FIGS. 4A and 4B are cross-sectional views of an embodiment of the display device according to the inventive concept, respectively:

FIG. 5 is a flowchart of an embodiment of a method of manufacturing the display device according to the inventive concept:

FIG. 6 is a cross-sectional view illustrating an embodiment of one operation of the method of manufacturing the display device according to the inventive concept:

FIG. 7 is a cross-sectional view illustrating an embodiment of one operation of the method of manufacturing the display device according to the inventive concept:

FIGS. 8A and 8B are cross-sectional views illustrating an embodiment of one operation of the method of manufacturing the display device according to the inventive concept, respectively:

FIGS. 9A and 9B are cross-sectional views illustrating an embodiment of one operation of the method of manufacturing the display device according to the inventive concept, respectively:

FIG. 10 is a cross-sectional view illustrating an embodiment of one operation of the method of manufacturing the display device according to the inventive concept:

FIG. 11 is a cross-sectional view illustrating an embodiment of one operation of the method of manufacturing the display device according to the inventive concept;

FIG. 12 is a cross-sectional view illustrating an embodiment of one operation of the method of manufacturing the display device according to the inventive concept;

FIGS. 13A and 13B are cross-sectional views illustrating an embodiment of one operation of the method of manufacturing the display device according to the inventive concept, respectively;

FIGS. 14A to 14C are cross-sectional views schematically illustrating an embodiment of a plurality of inorganic films according to the inventive concept, respectively; and

FIG. 15 is a cross-sectional view illustrating one operation of the method of an embodiment of manufacturing the display device according to the inventive concept.

### DETAILED DESCRIPTION

In the invention, various modifications may be made, various forms may be used, and illustrative embodiments will be illustrated in the drawings and described in detail in the text. However, this is not intended to limit the present invention to a specific form disclosed, and it will be understood that all changes, equivalents, or substitutes which fall in the spirit and technical scope of the invention should be included.

In this specification, it will be understood that when an element (or region, layer, portion, etc.) is referred to as being “on”, “connected to” or “coupled to” another element, it can be directly on, connected or coupled to the other element, or intervening elements may be present.

In the application, being “directly disposed” may mean that there is no layer, film, region, plate, or the like added between a part such as a layer, film, region, or plate and another part such as a layer, film, region, or plate. For example, being “directly disposed” may mean that no additional member such as an adhesive member is disposed between two layers or two members.

Like reference numerals refer to like elements throughout. In addition, in the drawings, the thicknesses, ratios, and dimensions of elements are exaggerated for effective description of the technical contents.

As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the present invention. Similarly, the second element may also be referred to as the first element. The terms of a singular form include plural forms unless otherwise specified.

Terms, such as “below”, “lower”, “above”, “upper” and the like, are used herein for ease of description to describe one element's relation to another element(s) as illustrated in the drawing figures. The above terms are relative concepts and are described based on the directions indicated in the drawings. In this specification, the expression “disposed on” may indicate a case of being disposed below as well as above any one member.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device and a method of manufacturing the display device in an embodiment of the inventive concept will be described with reference to the accompanying drawings.

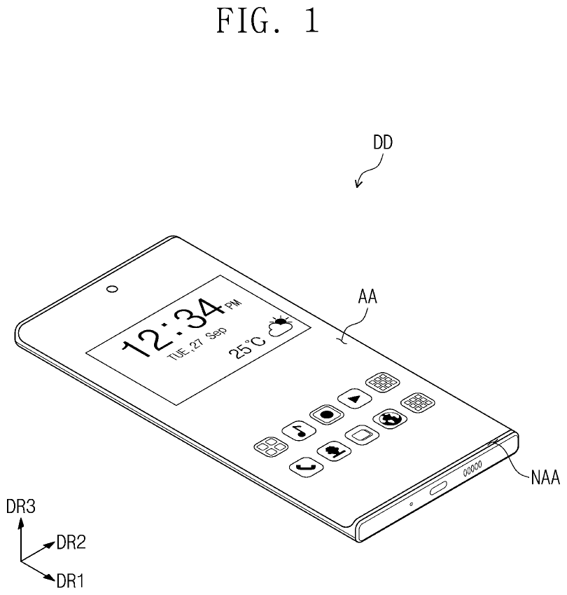

FIG. 1 is a combined perspective view of an embodiment of a display device according to the inventive concept.

The display device DD in an embodiment of the inventive concept illustrated in FIG. 1 may be activated according to an electrical signal. In an embodiment, the display device DD may be a mobile phone, a tablet computer, a monitor, a television, a car navigation system, a game machine, or a wearable device, for example, but the inventive concept is not limited thereto. FIG. 1 illustrates a mobile phone in an embodiment of the display device DD.

FIG. 1 and the following drawings illustrate a first direction DR1, a second direction DR2, and a third direction DR3, and directions indicated by the first to third directions DR1, DR2, and DR3 described herein are relative concepts and may be converted into other directions. In this specification, the first direction DR1 and the second direction DR2 are orthogonal to each other, and the third direction DR3 may be a normal direction of a plane defined by the first and second directions DR1 and DR2.

In this specification, the thickness direction of the display device DD may be parallel to the third direction DR3, which is the normal direction of the plane defined by the first and second directions DR1 and DR2. The front (or upper) surfaces and rear (or lower) surfaces of members constituting the display device DD may be defined based on the third direction DR3.

In this specification, the expression “plan view” may mean a view in a direction perpendicular to the plane defined by the first and second directions DR1 and DR2. In this specification, the term “overlapping” may mean overlapping in a plan view unless otherwise defined.

Referring to FIG. 1, the display device DD in an embodiment of the inventive concept may display an image through an active region AA. The active region AA may include a plane defined by the first direction DR1 and the second direction DR2. The active region AA may further include a curved surface bent from at least one side of a plane defined by the first and second directions DR1 and DR2.

A peripheral region NAA may be disposed adjacent to the active region AA.

The peripheral region NAA may surround the active region AA. Accordingly, the shape of the active region AA may be substantially defined by the peripheral region NAA. However, this is illustrated in an embodiment, and the peripheral region NAA may be disposed adjacent to only one side of the active region AA or may be omitted. The display device DD in an embodiment of the inventive concept may include active regions AA having various shapes and is not limited to any particular embodiment.

The display device DD in an embodiment of the inventive concept illustrated in FIG. 1 is illustrated as including two curved surfaces respectively bent from opposite sides of a plane defined by the first and second directions DR1 and DR2. However, the shape of the active region AA is not limited thereto. In an embodiment, the active region AA may include only the plane, and the active region AA may further include at least two or more, e.g., four curved surfaces respectively bent from the four sides of the plane, for example.

The display device DD in an embodiment of the inventive concept may sense an external input applied from the outside. The external input may include various types of inputs provided from the outside of the display device DD. In an embodiment, the external input may include not only a touch by a part of a user's body such as a user's hand, but also an external input (e.g., hovering) applied at a place close to or at a predetermined adjacent distance from the display device DD, for example. In addition, the external input may have various forms such as force, pressure, temperature, and light.

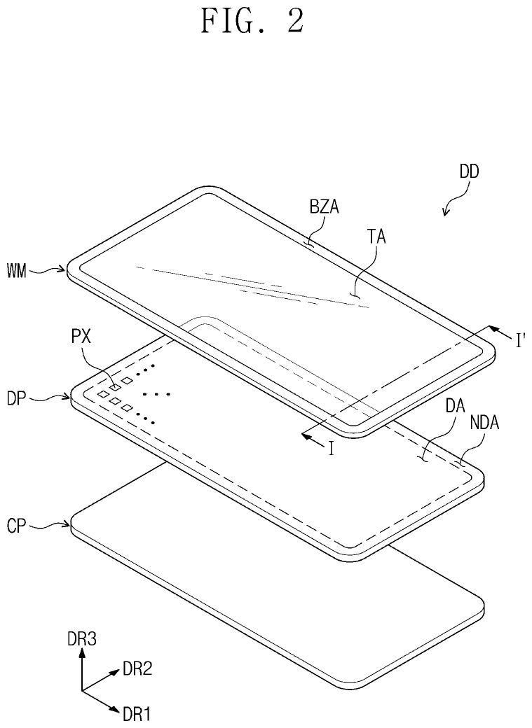

The display device DD in an embodiment of the inventive concept may include a display module. The display module may generate an image and detect pressure applied from the outside. The display module in an embodiment of the inventive concept may include a display panel DP (refer to FIG. 2). The display module in an embodiment of the inventive concept may further include a sensor layer and an optical layer which are disposed on the display panel DP (refer to FIG. 2). However, the inventive concept is not limited thereto, and in an embodiment of the inventive concept, the sensor layer or the optical layer may be omitted.

The display device DD in an embodiment of the inventive concept may further include various electronic modules. In an embodiment, the electronic modules may include at least any one of a camera, a speaker, a light sensor, or a heat sensor. The electronic module may sense an external subject received from the outside or provide a sound signal such as a voice to the outside, for example. The electronic module may include a plurality of elements, and the inventive concept is not limited to any particular embodiment.

Although not illustrated, the display device DD in an embodiment of the inventive concept may be a flexible display device that may be folded, bent, slidden, or rolled.

FIG. 2 is an exploded perspective view of an embodiment of the display device DD according to the inventive concept. FIG. 2 may be an exploded perspective view illustrating the elements included in the display device DD of FIG. 1.

Referring to FIG. 2, the display device DD in an embodiment of the inventive concept may include a display panel DP and a cover panel CP.

The display panel DP may display image information according to an electrical signal and transmit/receive information on an external input. The display panel DP may include a display layer and a sensor layer disposed on the display layer.

The display panel DP may be a light-emitting display panel. In an embodiment, the display panel DP may be an organic light-emitting display panel, an inorganic light-emitting display panel, an organic-inorganic display panel, a quantum dot display panel, a micro light-emitting diode (“LED”) display panel, or a nano LED display panel, for example.

The display panel DP may include a display region DA and a non-display region NDA. The display region DA may provide image information. A pixel PX may be disposed in the display region DA. The non-display region NDA may be disposed adjacent to the display region DA. The non-display region NDA may surround the display region DA. A driving circuit, a driving line, or the like for driving the display region DA may be disposed in the non-display region NDA. The display region DA and the non-display region NDA may respectively correspond to the active region AA and the peripheral region NAA of FIG. 1.

The display panel DP may include a plurality of pixels PX. Each of the pixels PX may display light in response to an electrical signal. The light displayed by the pixels PX may implement an image. Each of the pixels PX may include a display element. In an embodiment, the display element may be an organic light-emitting element, an inorganic light-emitting element, an organic-inorganic light-emitting element, a micro LED element, a nano LED element, a quantum dot light-emitting element, an electrophoretic element, an electrowetting element, or the like, for example.

The cover panel CP may be disposed below the display panel DP. The cover panel CP may have impact resistance characteristics, electromagnetic wave shielding characteristics, heat dissipation characteristics, and barrier characteristics so as to protect the display panel DP from an external impact and improve the visibility of the display panel DP. The cover panel CP according to the inventive concept will be described in detail later.

The display device DD in an embodiment of the inventive concept may further include a window module WM. The window module WM may effectively transmit image information, which is provided from the display panel DP, to the outside and protect the display panel DP from the outside.

The window module WM may be disposed on at least one of the upper portion or the lower portion of the display panel DP. FIG. 2 illustrates that the window module WM is disposed on the upper portion of the display panel DP. The window module WM may cover the entirety of the outer side of the display panel DP. The window module WM may be coupled to the display panel DP by an adhesive layer.

The window module WM may have a shape corresponding to the shape of the display panel DP. In the display device DD in an embodiment of the inventive concept, the window module WM may include or consist of an optically transparent insulating material. The window module WM may include a glass substrate or a polymer substrate. In an embodiment, the window module WM may include a chemically strengthened glass substrate, for example.

The window module WM may include a transmission portion TA and a bezel portion BZA. The transmission portion TA may correspond to the display region DA of the display panel DP, and the bezel portion BZA may correspond to the non-display region NDA of the display panel DP. The bezel portion BZA may define the shape of the transmission portion TA. The bezel portion BZA may be adjacent to and surround the transmission portion TA. However, the inventive concept is not limited to what is illustrated, and the bezel portion BZA may be disposed adjacent to only one side of the transmission portion TA, or a portion of the bezel portion BZA may be omitted.

The display device DD in an embodiment of the inventive concept may further include an adhesive layer, a polarizing film, or an impact absorbing layer which are disposed between the display panel DP and the window module WM. In addition, the display device DD in an embodiment of the inventive concept may further include a panel protection layer or a support plate disposed below the display panel DP. The display device DD may further include a housing that accommodates the display panel DP, the cover panel CP, or the like. The housing may be coupled to the window module WM.

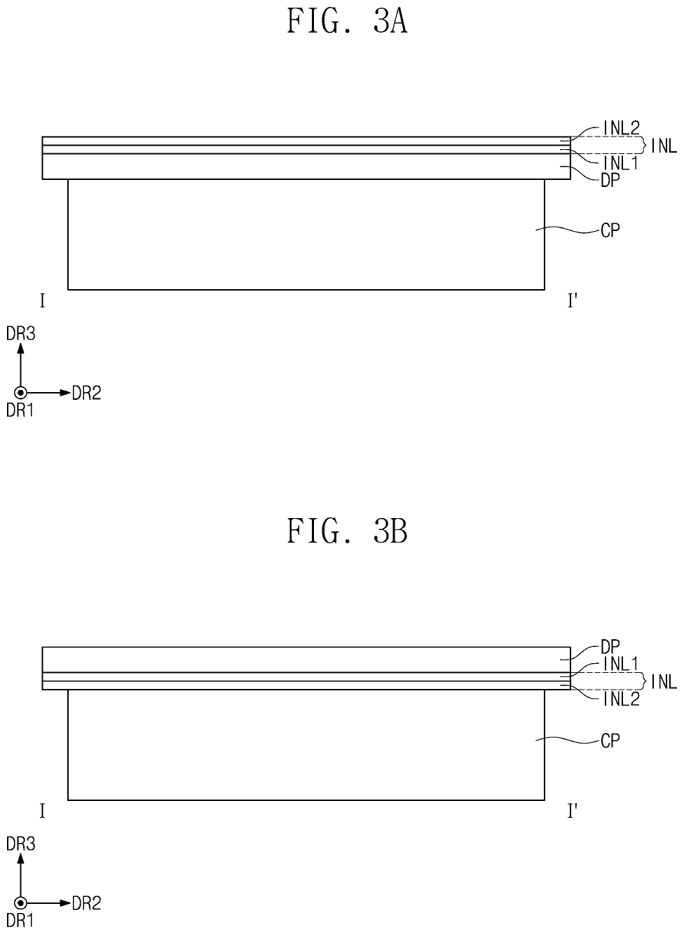

FIGS. 3A and 3B are cross-sectional views of an embodiment of the display device DD (refer to FIGS. 1 and 2) according to the inventive concept. Each of FIGS. 3A and 3B may illustrate a cross section of some elements corresponding to the section I-I′ of FIG. 2.

The display device DD (refer to FIGS. 1 and 2) in an embodiment of the inventive concept includes a cover panel CP, a display panel DP, and a plurality of inorganic films INL. Regarding the display panel DP, the contents described above with reference to FIG. 2 may be equally applied.

The cover panel CP according to the inventive concept may be a single-layered cover panel CP to which a multifunctional material integrally having various functions is applied. That is, the cover panel CP may not have a structure in which a plurality of functional layers is stacked. A material having desired functions as a multifunctional material may be selectively applied according to the type, structure, and application range of the display device DD (refer to FIGS. 1 and 2). In an embodiment, the multifunctional material applied to the cover panel CP may be a resin including or consisting of graphite, carbon nanofiber, metal particles, or the like, for example.

In addition, the cover panel CP according to the inventive concept may be disposed directly on the display panel DP or on a plurality of inorganic films INL. Here, the expression “being directly disposed” may mean that an adhesive layer is not disposed between the cover panel CP and the display panel DP or between the cover panel CP and the plurality of inorganic films INL. That is, the display device DD may not have a structure in which the cover panel CP is attached to the display panel DP or the plurality of inorganic films INL by a separate adhesive layer. A manufacturing method for forming the cover panel CP directly on the display panel DP or the plurality of inorganic films INL will be described later.

The cover panel CP in an embodiment of the inventive concept may be disposed on the display panel DP. In an embodiment, as illustrated in FIG. 3A, the cover panel CP may be disposed in contact with one surface of the display panel DP, for example. In addition, as illustrated in FIG. 3B, the cover panel CP may be spaced apart from the display panel DP with the plurality of inorganic films INL interposed therebetween.

The thickness of the cover panel CP in an embodiment of the inventive concept may be about 100 micrometers (μm) to about 300 μm. The cover panel CP may preferably have a thickness of about 150 μm to about 250 μm, e.g., about 200 μm. When the thickness of the cover panel CP is within the above range, impact resistance characteristics, heat dissipation characteristics, or the like may be sufficiently secured.

The width of the cover panel CP in an embodiment of the inventive concept may be smaller than that of the display panel DP. Here, the width may mean a length in the second direction DR2. FIGS. 3A and 3B illustrate that the width of the cover panel CP is smaller than that of the display panel DP. Without being limited thereto, however, the width of the cover panel CP may vary depending on the type and structure of the display device DD (refer to FIGS. 1 and 2). In an embodiment, the width of the cover panel CP may be substantially the same as the width of the display panel DP, for example.

The plurality of inorganic films INL according to the inventive concept may be disposed on the display panel DP. The plurality of inorganic films INL in an embodiment of the inventive concept may be disposed directly on at least one surface of the display panel DP. Here, the expression “being directly disposed” may mean that a separate adhesive layer is not disposed between the display panel DP and the plurality of inorganic films INL.

In an embodiment, as illustrated in FIG. 3A, the plurality of inorganic films INL may be disposed directly on the upper surface of the display panel DP, for example. Here, the plurality of inorganic films INL may be spaced apart from the cover panel CP with the display panel DP interposed therebetween.

In addition, as illustrated in FIG. 3B, the plurality of inorganic films INL may be disposed directly on the lower surface of the display panel DP. Here, the plurality of inorganic films INL may be disposed between the display panel DP and the cover panel CP.

Referring to FIGS. 3A and 3B, the plurality of inorganic films INL may include a first inorganic film INL1 and a second inorganic film INL2. The first inorganic film INL1 may be disposed in contact with the display panel DP, and the second inorganic film INL2 may be disposed on the first inorganic film INL1.

The plurality of inorganic films INL in an embodiment of the inventive concept may respectively have thermal expansion coefficients different from each other. That is, the thermal expansion coefficients of the first inorganic film INL1 and the second inorganic film INL2, respectively, may be different from each other. An inorganic film adjacent to the cover panel CP may have a smaller thermal expansion coefficient.

In an embodiment, in FIG. 3A, the thermal expansion coefficient of the first inorganic film INL1 may be smaller than that of the second inorganic film INL2, for example. In addition, in FIG. 3B, the thermal expansion coefficient of the first inorganic film INL1 may be greater than that of the second inorganic film INL2. Accordingly, in a method of manufacturing the display device to be described later, the edge portion of a resin RS for the cover panel may be evenly applied.

Any materials may be applied to the plurality of inorganic films INL in an embodiment of the inventive concept as long as the materials respectively have thermal expansion coefficients different from each other. In an embodiment, the plurality of inorganic films INL may include or consist of silicon nitride (SiNₓ), silicon oxide (SiOₓ), or titanium nitride (TiN), for example.

The total thickness of the plurality of inorganic films INL in an embodiment of the inventive concept may be about 10000 angstroms (Å) or less. The thickness of each inorganic film included in the plurality of inorganic films INL may be adjusted.

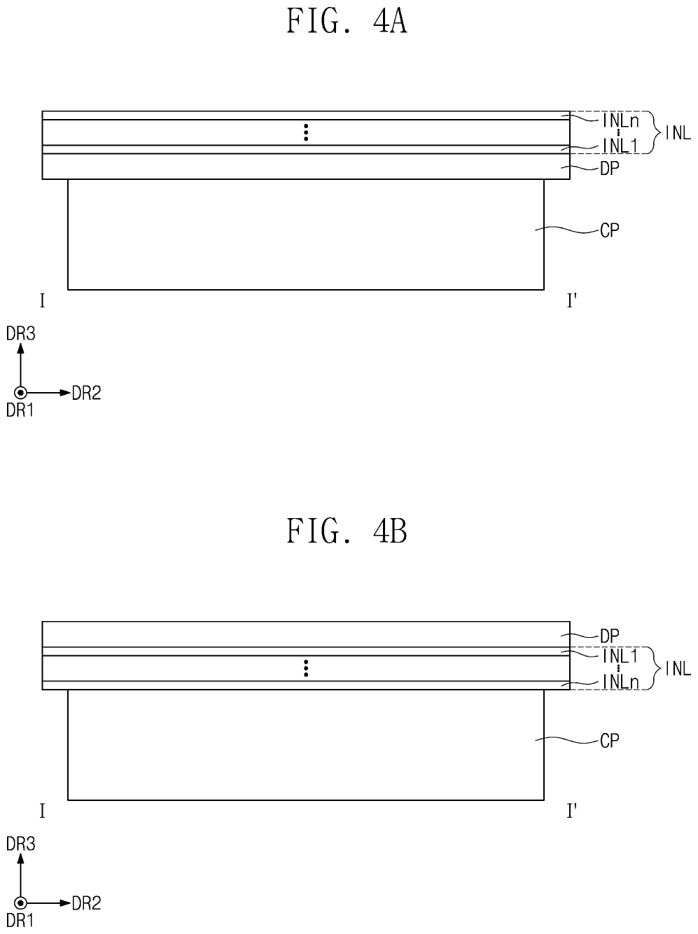

FIGS. 4A and 4B are cross-sectional views of an embodiment of the display device DD (refer to FIGS. 1 and 2) according to the inventive concept, respectively. Each of FIGS. 4A and 4B may illustrate a cross section of some elements corresponding to the section I-I′ of FIG. 2.

Referring to FIGS. 4A and 4B, the plurality of inorganic films INL may include first to n-th inorganic films INL1 to INLn. The thermal expansion coefficients of the first to n-th inorganic films INL1 to INLn may be different from each other. As the cover panel CP is more adjacent to an inorganic film, the inorganic film may have a smaller thermal expansion coefficient.

In an embodiment, the thermal expansion coefficient of the first inorganic film INL1 of FIG. 4A may be smaller than that of the n-th inorganic film INLn, for example. In addition, the thermal expansion coefficient(s) of the inorganic film(s) disposed between the first inorganic film INL1 and the n-th inorganic film INLn may have a value between the thermal expansion coefficient of the first inorganic film INL1 and the thermal expansion coefficient of the n-th inorganic film INLn, and an inorganic film(s) more adjacent to the first inorganic film INL1 may have a smaller thermal expansion coefficient.

In addition, the thermal expansion coefficient of the first inorganic film INL1 of FIG. 4B may be greater than that of the n-th inorganic film INLn. In addition, the thermal expansion coefficient(s) of the inorganic film(s) disposed between the first inorganic film INL1 and the n-th inorganic film INLn may have a value between the thermal expansion coefficient of the first inorganic film INL1 and the thermal expansion coefficient of the n-th inorganic film INLn, and an inorganic film(s) more adjacent to the first inorganic film INL1 may have a greater thermal expansion coefficient.

The contents described above with reference to FIGS. 3A and 3B may be respectively applied to FIGS. 4A and 4B except that the plurality of inorganic films INL of FIGS. 4A and 4B includes three or more inorganic films.

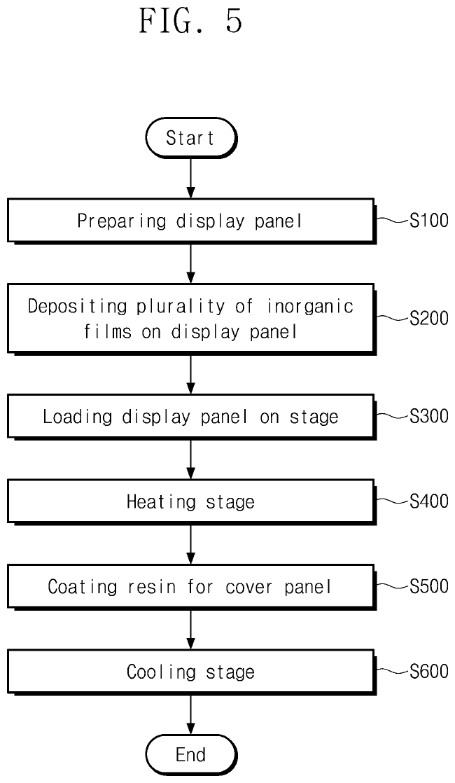

FIG. 5 is a flowchart of an embodiment of a method of manufacturing the display device according to the inventive concept.

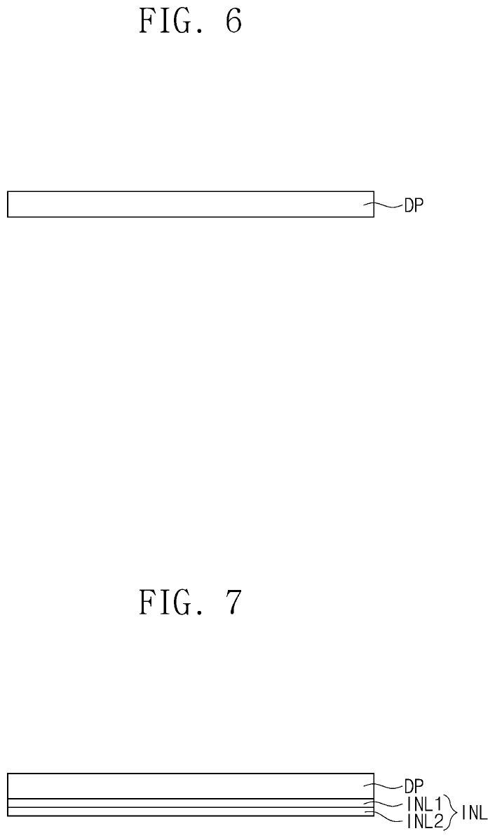

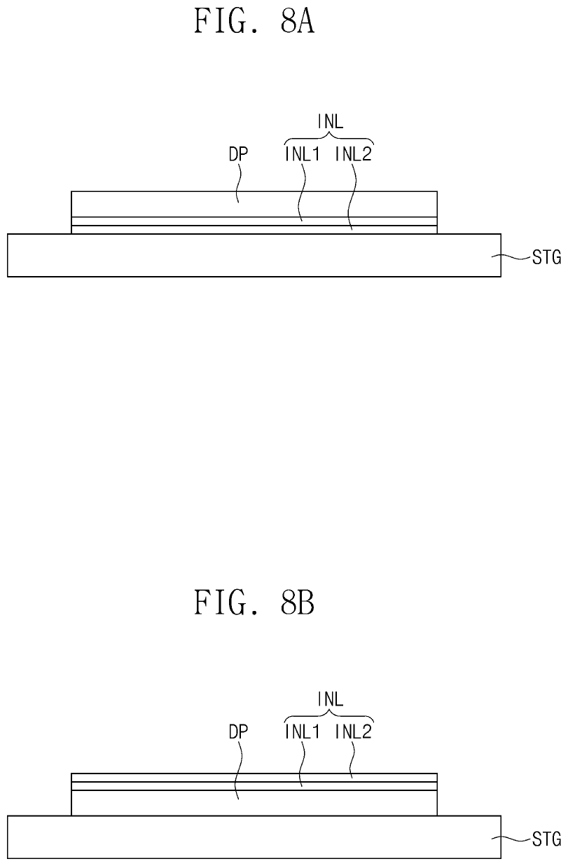

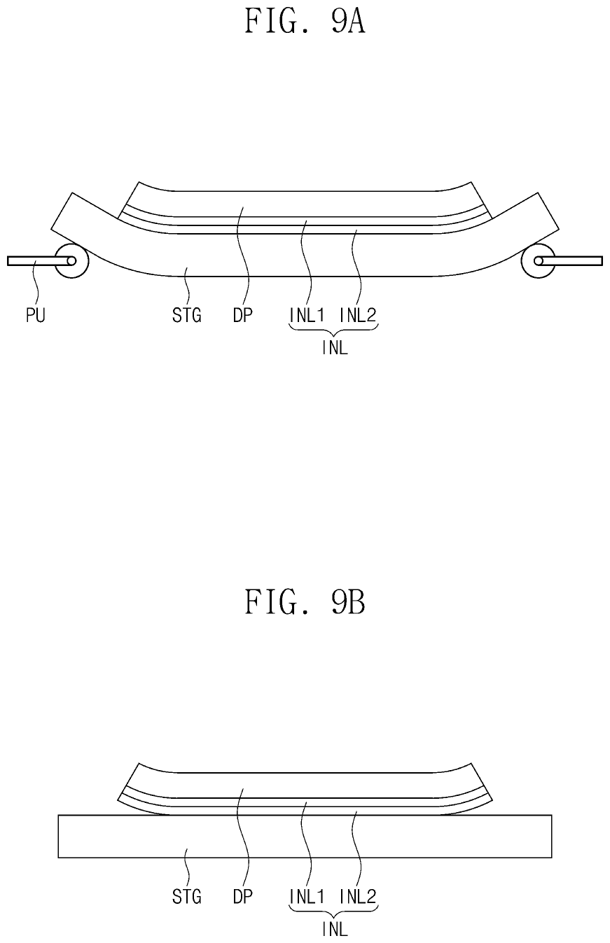

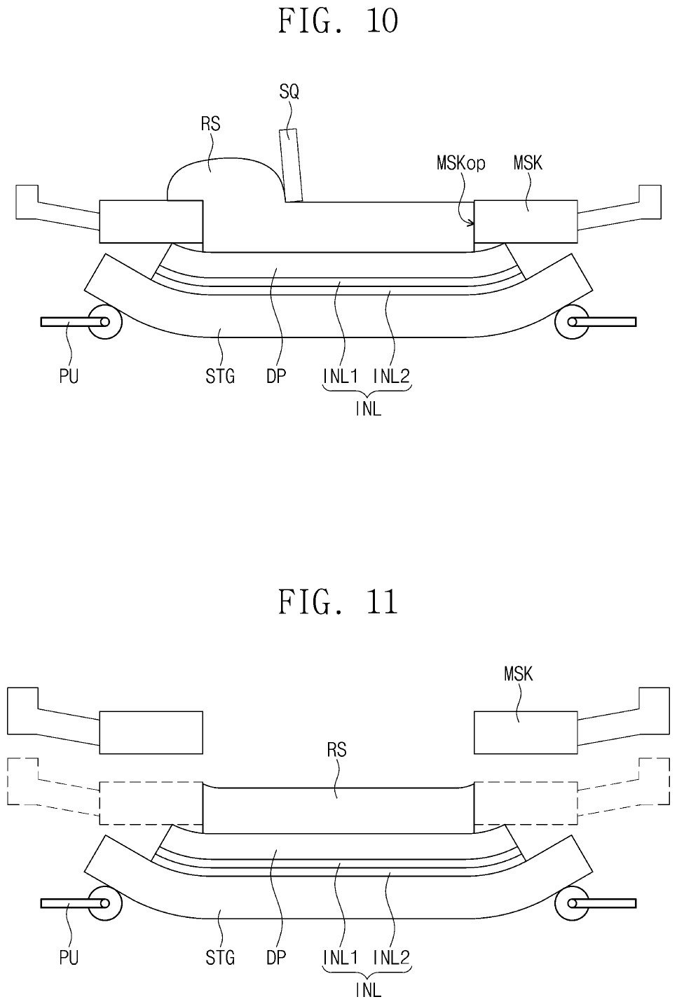

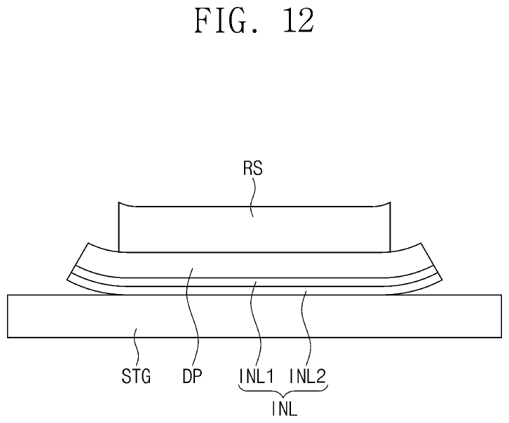

The method of manufacturing the display device according to the inventive concept includes preparing a display panel DP (refer to FIG. 6) (S100), depositing a plurality of inorganic films INL (refer to FIG. 7) on the display panel DP (refer to FIG. 7) (S200), loading the display panel DP (refer to FIGS. 8A and 8B) on a stage STG (refer to FIGS. 8A and 8B) (S300), heating the stage STG (refer to FIGS. 9A and 9B) (S400), coating the display panel DP (refer to FIG. 10) with a resin RS (refer to FIG. 10) for a cover panel (S500), and cooling the stage STG (refer to FIG. 12). (S600). Each operation will be described below with reference to the drawings.

FIG. 6 is a cross-sectional view illustrating an embodiment of one operation of the method of manufacturing the display device according to the inventive concept. FIG. 6 may be a cross-sectional view illustrating the preparing of the display panel DP (S100, refer to FIG. 5).

Regarding the display panel DP of FIG. 6, the contents described above with respect to FIGS. 2 to 4B may be equally applied.

FIG. 7 is a cross-sectional view illustrating an embodiment of one operation of the method of manufacturing the display device according to the inventive concept. FIG. 7 may be a cross-sectional view illustrating the depositing of a plurality of inorganic films INL on the display panel DP (S200, refer to FIG. 5).

In an embodiment of the inventive concept, the plurality of inorganic films INL may be deposited on at least one of the upper surface or lower surface of the display panel DP. The plurality of inorganic films INL may be deposited by a chemical vapor deposition method.

The depositing of a plurality of inorganic films INL (S200, refer to FIG. 5) in an embodiment of the inventive concept may include depositing a first inorganic film INL1 on the display panel DP and depositing a second inorganic film INL2 on the first inorganic film INL1.

Unlike the embodiment illustrated in FIG. 7, depositing a plurality of inorganic films INL (S200, refer to FIG. 5) may include sequentially depositing first to n-th inorganic films INL1 to INLn on the display panel DP (refer to FIGS. 4A and 4B), where n is an integer greater than or equal to 3.

As described above, the plurality of inorganic films INL in an embodiment of the inventive concept may respectively have thermal expansion coefficients different from each other. In an embodiment, the thermal expansion coefficient of the first inorganic film INL1 in FIG. 7 may be greater or smaller than that of the second inorganic film INL2, for example.

Regarding the plurality of inorganic films INL of FIG. 7, the contents described above with respect to FIGS. 3A to 4B may be equally applied.

FIGS. 8A and 8B are cross-sectional views illustrating an embodiment of one operation of the method of manufacturing the display device according to the inventive concept. Each of FIGS. 8A and 8B may be a cross-sectional view illustrating the loading of the display panel DP on the stage STG (S300, refer to FIG. 5).

The method of manufacturing the display device in an embodiment of the inventive concept may include loading the display panel DP, on which a plurality of inorganic films INL are deposited, on the stage STG in order to screen-print the resin RS (refer to FIG. 10) for the cover panel (S300, refer to FIG. 5).

When the thermal expansion coefficient of the first inorganic film INL1 is smaller than that of the second inorganic film INL2, as illustrated in FIG. 8A, the display panel DP, on which the plurality of inorganic films INL is deposited, may be loaded so that the second inorganic film INL2 may be adjacent to the stage STG.

When the thermal expansion coefficient of the first inorganic film INL1 is greater than that of the second inorganic film INL2, as illustrated in FIG. 8B, the display panel DP, on which the plurality of inorganic films INL is deposited, may be loaded so that the display panel DP may be adjacent to the stage STG.

Hereinafter, FIGS. 9A to 13B representatively describe a case illustrated in FIG. 8A.

FIGS. 9A and 9B are cross-sectional views illustrating an embodiment of one operation of the method of manufacturing the display device according to the inventive concept, respectively. Each of FIGS. 9A and 9B may be a cross-sectional view illustrating the heating of the stage STG (S400, refer to FIG. 5).

Although a heating method is not illustrated, any method may be applied as long as it is capable of transferring heat to the plurality of inorganic films INL by heating the stage STG.

Referring to each of FIGS. 9A and 9B, the heating of the stage STG (S400, refer to FIG. 5) may include bending an edge portion of the display panel DP in a direction opposite to the stage STG by heating.

Specifically, when the plurality of inorganic films INL respectively having different thermal expansion coefficients are heated, the expansion degrees thereof may be different from each other. Accordingly, the edge portion of the display panel DP, on which the plurality of inorganic films INL is deposited, may be bent by heating.

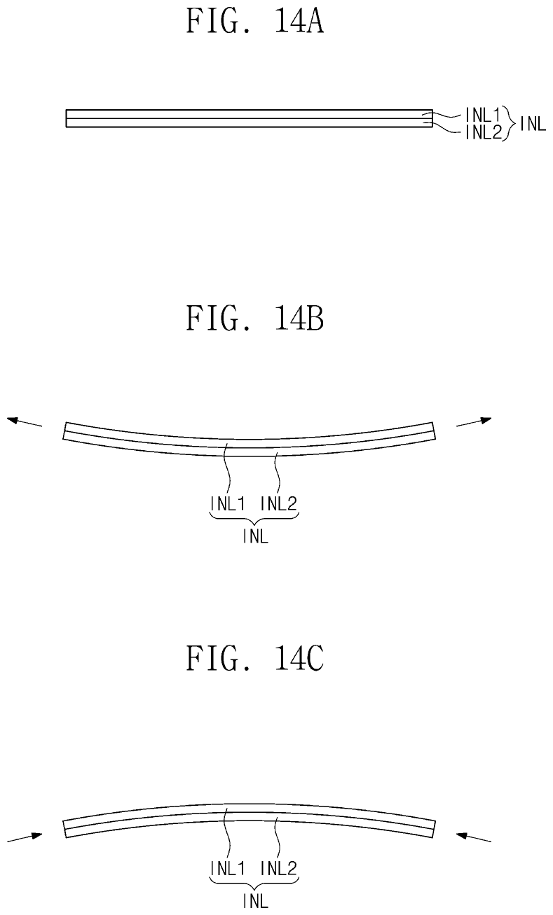

In an embodiment, when the thermal expansion coefficient of the first inorganic film INL1 is smaller than that of the second inorganic film INL2, the second inorganic film INL2 may expand relatively more than the first inorganic film INL1, for example. Accordingly, the edge portion of the display panel DP, on which the first and second inorganic films INL1 and INL2 are deposited, may be bent in a direction opposite to the stage STG. In an embodiment, the edge portion of the display panel DP, on which the first and second inorganic films INL1 and INL2 are deposited, may be bent in a direction away from the stage STG, for example. The phenomenon that the edge portions of the plurality of inorganic films INL may be bent due to different thermal expansion coefficients will be described later again with reference to FIGS. 14A to 14C.

Referring to FIG. 9A, the heating of the stage STG (S400, refer to FIG. 5) may further include pushing the edge portion of the display panel DP in a direction opposite to the stage STG with a pusher PU. Specifically, as the edge portion of the display panel DP, on which the first and second inorganic films INL1 and INL2 are deposited, is bent in a direction opposite to the stage STG, the pusher PU may be applied so that the stage STG may support the edge portion. Unlike the case in which the pusher PU is applied in FIG. 9A, the pusher PU may not be applied as illustrated in FIG. 9B. In this case, the stage STG may maintain a flat state.

FIG. 10 is a cross-sectional view illustrating an embodiment of one operation of the method of manufacturing the display device according to the inventive concept. FIG. 11 is a cross-sectional view illustrating an embodiment of one operation of the method of manufacturing the display device according to the inventive concept. Each of FIGS. 10 and 11 may be a cross-sectional view illustrating the coating of the display panel DP with the resin RS for the cover panel (S500, refer to FIG. 5).

The coating of the resin RS for the cover panel (S500, refer to FIG. 5) may further include disposing a mask MSK, in which an opening MSKop is defined, on the display panel DP, coating the resin RS for the cover panel, and separating the mask MSK. FIG. 11 illustrates the separating of the mask MSK. The mask MSK may be a metal mask.

In the disposing of the mask MSK, in which the opening MSKop is defined, on the display panel DP, the opening MSKop of the mask MSK may correspond to the range in which the cover panel CP is to be formed in the display panel DP. FIG. 10 illustrates that the opening MSKop of the mask MSK is smaller than the width of the display panel DP, but is not limited thereto and may be substantially equal to the width of the display panel DP.

With the mask MSK disposed on the display panel DP, the resin RS for the cover panel may be supplied to the opening MSKop of the mask MSK, and the surface of the resin RS for the cover panel may be made flat by a squeegee SQ. The resin RS for the cover panel may be coated in the thickness of the mask MSK. The thickness of the coated resin RS for the cover panel may be about 100 μm to about 300 μm. Preferably, the thickness of the coated resin RS for the cover panel may be about 150 μm to about 250 μm.

The resin RS for the cover panel may be a multifunctional material integrally having various functions. Accordingly, since a process of stacking a plurality of functional layers by an adhesive layer is unnecessary and the cover panel including multifunctional material may be formed through a screen-printing process, processability may be improved. Materials having functions such as cushioning, heat dissipation, and shielding may be applied as a multifunctional material. In an embodiment, the multifunctional material applied to the cover panel CP may be a resin including or consisting of graphite, carbon nanofiber, metal particles, or the like, for example.

Since the resin RS for the cover panel may be coated directly on the display panel DP to form the cover panel CP (refer to FIG. 2), a separate adhesive layer between the cover panel CP and the display panel DP is not desired, thus improving processability.

Unlike the embodiment illustrated in FIG. 10, even when the display panel DP, on which a plurality of inorganic films INL is deposited, is disposed on the stage STG as illustrated in FIG. 8B, the cover panel CP (refer to FIG. 2) may be formed by directly coating the plurality of inorganic films INL with the resin RS for the cover panel. Accordingly, even in this case, a separate adhesive layer between the cover panel CP and the plurality of inorganic films INL may not be desired.

Referring to FIG. 11, in the separating of the mask MSK after coating the resin RS for the cover panel, the resin RS for the cover panel may be dragged up by the mask MSK so that the edge portion thereof protrudes (forming a bump). This may be caused due to the interfacial tension between the mask MSK and the resin RS for the cover panel.

Regarding this matter, unlike the invention, when the edge portion of the resin RS for the cover panel is cured in a state in which the edge portion of the resin RS for the cover panel is dragged up, the flatness of the surface may not be uniform because the edge portion of the cover panel CP (refer to FIG. 2) protrudes.

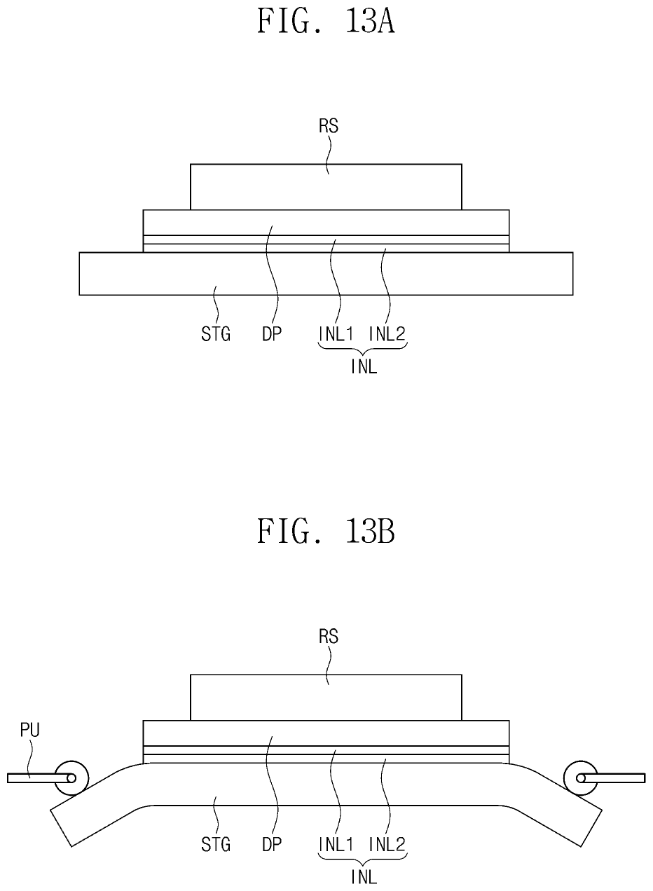

FIG. 12 is a cross-sectional view illustrating an embodiment of one operation of the method of manufacturing the display device according to the inventive concept. FIGS. 13A and 13B are cross-sectional views illustrating an embodiment of one operation of the method of manufacturing the display device in an embodiment of the inventive concept, respectively. FIGS. 12 to 13B may be cross-sectional views illustrating the cooling of the stage STG (S600, refer to FIG. 5), respectively.

Referring to FIG. 12, in the cooling of the stage STG (S600, refer to FIG. 5), the pusher PU is removed and the stage STG may be cooled without being lifted. Any method may be applied as long as the method may cool the plurality of inorganic films INL by cooling the stage STG.

Referring to each of FIGS. 13A and 13B, the cooling of the stage STG (S600, refer to FIG. 5) may include bending the edge portion of the display panel DP in the direction of the stage STG by cooling. Accordingly, the display panel DP may be flattened by cooling.

Specifically, the plurality of inorganic films INL having different thermal expansion coefficients may have different degrees of contraction when they are cooled. Accordingly, by cooling, the display panel DP, on which the plurality of inorganic films INL is deposited, may be bent in a direction opposite to the direction in which it is bent when the edge portion thereof is heated.

In an embodiment, when the thermal expansion coefficient of the first inorganic film INL1 is smaller than that of the second inorganic film INL2, the second inorganic film INL2 contracts relatively more than the first inorganic film INL1, for example. Accordingly, by the heating (S400), the edge portion of the display panel DP, on which the first and second inorganic films INL1 and INL2 are deposited and the edge portion of which is bent in a direction opposite to the stage STG, may be restored in the direction of the stage STG. The phenomenon that the edge portions of the plurality of inorganic films INL may be bent due to different thermal expansion coefficients will be described later again with reference to FIGS. 14A to 14C.

As illustrated in FIG. 13B, the cooling (S600, refer to FIG. 5) may further include pushing the edge portion of the stage STG in a direction opposite to the display panel DP by applying the pusher PU. Specifically, the pusher PU may be applied to assist bending the edge portion of the display panel DP, on which the first and second inorganic films INL1 and INL2 are deposited, in the direction of the stage STG by cooling.

As a result, the cooling of the stage STG (S600, refer to FIG. 5) may include flattening the edge portion of the resin RS for the cover panel, which has been dragged up by the mask (MSK, refer to FIG. 11). Accordingly, the flatness of the cover panel (CP, refer to FIG. 2) may be improved.

The method of manufacturing the display device in an embodiment of the inventive concept may further include curing the resin RS for the cover panel after flattening the edge portion of the resin RS for the cover panel. Light curing or thermal curing may be used. Accordingly, the cover panel CP (refer to FIG. 2) having improved flatness may be formed directly on the display panel DP without a separate adhesive layer.

FIGS. 14A to 14C are cross-sectional views schematically illustrating an embodiment of a plurality of inorganic films INL according to the inventive concept. FIGS. 14A to 14C may be schematic diagrams for explaining the bending of the first and second inorganic films INL1 and INL2 having different thermal expansion coefficients.

FIGS. 14A to 14C illustrate cases in which the thermal expansion coefficient of the first inorganic film INL1 is smaller than that of the second inorganic film INL2.

FIG. 14A illustrates the equilibrium state of the first inorganic film INL1 and the second inorganic film INL2 disposed on the first inorganic film INL1.

FIG. 14B illustrates a state in which the first and second inorganic films INL1 and INL2 are expanded by heating. In this case, as the second inorganic film INL2 having a greater thermal expansion coefficient expands more than the first inorganic film INL1, the first and second inorganic films INL1 and INL2 may be bent in the direction of the first inorganic film INL1.

FIG. 14C illustrates a state in which the first and second inorganic films INL1 and INL2 are contracted by cooling. In this case, as the second inorganic film INL2 having a greater thermal expansion coefficient contracts more than the first inorganic film INL1, the first and second inorganic films INL1 and INL2 may be bent in the direction of the second inorganic film INL2.

In the separating of the mask MSK (refer to FIG. 11), compensation may be made in advance as much as the resin RS (refer to FIG. 11) for the cover panel is dragged up by the bending of the plurality of inorganic films INL1 and INL2.

Specifically, up to the operation of separating the mask MSK (refer to FIG. 11), the edge portion of the display panel DP (refer to FIG. 11) may be bent as much as the resin RS (refer to FIG. 11) for the cover panel is dragged up. In addition, after the mask MSK (refer to FIG. 11) is separated, in the process of restoring the bent edge portion of the display panel DP (refer to FIG. 11) by cooling the plurality of inorganic films INL1 and INL2 again, the edge portion of the resin RS (refer to FIG. 11) for the cover panel may also be flattened.

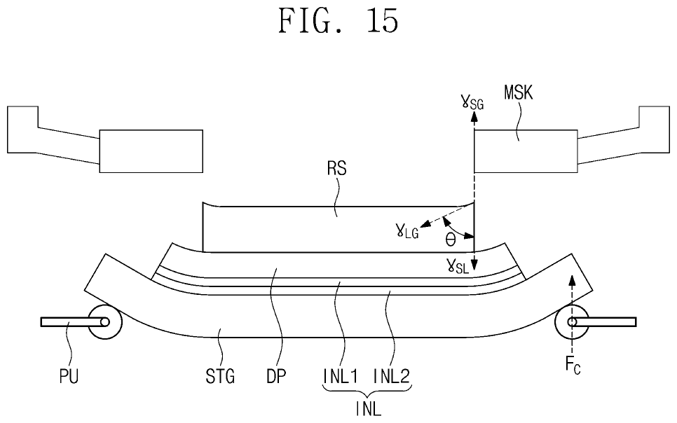

FIG. 15 is a cross-sectional view illustrating an embodiment of one operation of the method of manufacturing the display device according to the inventive concept. FIG. 15 shows factors that may be considered to design the magnitude of a force Fc of a pusher PU, which pushes the stage STG, when the pusher PU is applied in the heating of the stage STG (S400, refer to FIG. 5).

The magnitude of the force Fc applied by the pusher PU, which pushes the stage STG, may be expressed by Equation 1 below.

F_{C}=a*F_{R} [Equation 1]

In Equation 1, a may denote a resistance coefficient between the display panel DP and the stage STG. The value of the resistance coefficient may vary depending on the size of the display panel DP. F_{R} may denote an interfacial tension when the mask MSK is separated. The interfacial tension (F_{R}) may be expressed by Equation 2 below.

F_{R}=γ_{SG}−γ_{SL}−λ_{LG}*COSΘ [Equation 2]

In Equation 2, γ_{SG} may be an interfacial energy of the mask MSK, γ_{SL} may be an interfacial energy between the mask MSK and the resin RS for the cover panel, γ_{LG} may be an interfacial energy of the resin RS for the cover panel, and Θ may denote a contact angle between the mask MSK and the resin RS for the cover panel.

As described above, the display device according to the inventive concept may include an integrated cover panel having an edge portion having uniform flatness.

In addition, the method of manufacturing the display device according to the inventive concept may improve the flatness of the integrated cover panel by applying a screen-printing process which improves coating quality.

Although the above has been described with reference to preferred embodiments of the inventive concept, those skilled in the art or those of ordinary skill in the art will understand that various modifications and changes may be made to the inventive concept within the scope that does not depart from the spirit and technical field of the inventive concept described in the claims to be described later.

Accordingly, the technical scope of the inventive concept should not be limited to the content described in the detailed description of the specification, but should be determined by the claims described hereinafter.

What is claimed is:

1. A method for manufacturing a display device, the method comprising:
preparing a display panel;
depositing a plurality of inorganic films having different thermal expansion coefficients, respectively, on the display panel;
loading the display panel on a stage;
heating the stage;
coating the display panel with a resin for a cover panel; and
cooling the stage.

2. The method of claim 1, wherein the heating comprises bending an edge portion of the display panel in a direction opposite to the stage by heating.

3. The method of claim 1, wherein the heating comprises pushing an edge portion of the display panel in a direction opposite to the stage with a pusher.

4. The method of claim 1, wherein the cooling comprises bending an edge portion of the display panel in a direction of the stage by cooling.

5. The method of claim 1, wherein the cooling comprises flattening an edge portion of a coated resin.

6. The method of claim 1, wherein:
the depositing the plurality of inorganic films comprises depositing a first inorganic film on the display panel and a second inorganic film on the first inorganic film;
a thermal expansion coefficient of the first inorganic film is smaller than a thermal expansion coefficient of the second inorganic film; and
the loading the display panel includes loading the second inorganic film adjacent to the stage.

7. The method of claim 6, wherein the heating the stage comprises bending edge portions of the plurality of inorganic films in a direction of the display panel as the second inorganic film expands more than the first inorganic film.

8. The method of claim 1, wherein:
the depositing the plurality of inorganic films comprises depositing a first inorganic film on the display panel and a second inorganic film on the first inorganic film;
a thermal expansion coefficient of the first inorganic film is greater than a thermal expansion coefficient of the second inorganic film; and
the loading the display panel includes loading the display panel adjacent to the stage.

9. The method of claim 8, wherein the heating the stage comprises bending edge portions of the plurality of inorganic films in a direction opposite to the display panel as the first inorganic film expands more than the second inorganic film.

10. The method of claim 1, wherein the coating the resin further comprises:
disposing a mask, in which an opening is defined, on the display panel;
coating the resin; and
separating the mask.

11. The method of claim 1, further comprising curing the resin.

12. The method of claim 1, wherein:
the depositing the plurality of inorganic films comprises sequentially depositing a first inorganic film, a second inorganic film, and a third inorganic film on the display panel;
a thermal expansion coefficient of the first inorganic film is smaller than a thermal expansion coefficient of the third inorganic film;
a thermal expansion coefficient of the second inorganic film has a value between the thermal expansion coefficient of the first inorganic film and the thermal expansion coefficient of the third inorganic film; and
the loading the display panel includes loading the display panel adjacent to the stage.

13. The method of claim 1, wherein:
the depositing the plurality of inorganic films comprises sequentially depositing a first inorganic film, a second inorganic film, and a third inorganic film on the display panel;
a thermal expansion coefficient of the first inorganic film is greater than a thermal expansion coefficient of the third inorganic film;
a thermal expansion coefficient of the second inorganic film has a value between the thermal expansion coefficient of the first inorganic film and the thermal expansion coefficient of the third inorganic film; and
the loading the display panel includes loading the display panel adjacent to the stage.

14. A method for manufacturing a display device, the method comprising:
preparing a display panel;
depositing a plurality of inorganic films on the display panel;
loading the display panel on a stage;
bending an edge portion of the display panel in a direction opposite to the stage;
coating the display panel with a resin for a cover panel; and
flattening a bent edge portion of the display panel.

15. The method of claim 14, wherein the plurality of inorganic films respectively has thermal expansion coefficients different from each other.

16. The method of claim 14, wherein the bending the edge portion of the display panel in the direction opposite to the stage comprises heating the stage.

17. The method of claim 14, wherein the flattening the bent edge portion of the display panel comprises cooling the stage.

18. A display device comprising:
a cover panel;
a display panel disposed on the cover panel; and
a plurality of inorganic films having different thermal expansion coefficients, respectively, and disposed on the cover panel.

19. The display device of claim 18, wherein:
the plurality of inorganic films is spaced apart from the cover panel with the display panel interposed therebetween;
the plurality of inorganic films comprises a first inorganic film disposed in contact with the display panel and a second inorganic film disposed on the first inorganic film; and
a thermal expansion coefficient of the first inorganic film is smaller than a thermal expansion coefficient of the second inorganic film.

20. The display device of claim 18, wherein:
the plurality of inorganic films is disposed between the display panel and the cover panel;
the plurality of inorganic films comprises a first inorganic film disposed in contact with the display panel and a second inorganic film disposed on the first inorganic film; and
a thermal expansion coefficient of the first inorganic film is greater than a thermal expansion coefficient of the second inorganic film.
